(19) United States
(12) Patent Application Publication
(10) Pub. No.: US 2020/0259314 A1
(43) Pub. Date: Aug. 13, 2020

(54) SYSTEMS INCLUDING VERTICAL CAVITY SURFACE EMITTING LASERS

(71) Applicant: The Regents of the University of California, Oakland, CA (US)

(72) Inventors: Jared Kearns, Goleta, CA (US); Charles Forman, Fremont, CA (US); Dan Cohen, Santa Barbara, CA (US); Kenneth S. Kosik, Santa Barbara, CA (US); Shuji Nakamura, Santa Barbara, CA (US)

(73) Assignee: The Regents of the University of California, Oakland, CA (US)

(21) Appl. No.: 16/760,286

(22) PCT Filed: Oct. 31, 2018
(86) PCT No.: PCT/US18/58453

§ 371 Date: Apr. 29, 2020

Related U.S. Application Data
(60) Provisional application No. 62/579,420, filed on Oct. 31, 2017.
(60) Provisional application No. 62/579,330, filed on Oct. 31, 2017.
(60) Provisional application No. 62/579,341, filed on Oct. 31, 2017.

(51) Int. Cl. H01S 5/183; H01S 5/42; H01S 5/323; H01S 5/00; G01N 21/64; G02B 21/06; H01S 5/02; H01S 5/022

(52) U.S. Cl. CPC H01S 5/18305; H01S 5/423; H01S 5/32341; H01S 5/18388; H01S 5/0085; G01N 2201/0612; G02B 21/06; H01S 5/0216; H01S 5/02284; G01N 2021/6478; G01N 21/6458

(57) ABSTRACT

A sensing apparatus, an illumination system, and a data communication system including a Vertical Cavity Surface Emitting Laser (VCSEL) or VCSEL array.

### CROSS REFERENCE TO RELATED APPLICATIONS

This application claims the benefit under 35 U.S.C. Section 119(e) of the following co-pending and commonly-assigned U.S. applications: U.S. Provisional Patent Application No. 62/579,420, filed Oct. 31, 2017, by Jared Kearns, Charles Forman, Dan Cohen, Kenneth S. Kosik, and Shuji Nakamura, entitled “III-NITRIDE SURFACE EMITTING LASER FLUORESCENT SENSOR,” Attorney's Docket No. 30794.664-US-P1 (2018-253); U.S. Provisional Patent Application No. 62/579,330, filed Oct. 31, 2017, by Jared Kearns, Charles Forman, and Shuji Nakamura, entitled “III-NITRIDE VERTICAL CAVITY SURFACE EMITTING LASER (VCSEL) WHITE LIGHT ILLUMINATlON SYSTEM,” Attorney's Docket No. 30794.665-US-P1 (2018-254); and U.S. Provisional Patent Application No. 62/579,341, filed Oct. 31, 2017, by Jared Kearns, Charles Forman, and Shuji Nakamura., entitled “POLARIZATION LOCKED COMMUNICATION USING III-NITRIDE M-PLANE VERTICAL CAVITY SURFACE EMITTING LASERS (VCSELS),” Attorney's Docket No. 30794.664-US-P1 (2018-253);

all of which applications are incorporated by reference herein.

### STATEMENT REGARDING FEDERALLY SPONSORED RESEARCH AND DEVELOPMENT

This invention was made with Government support under Giant (or Contract) No. W911NF-17-1-0093, awarded by the US ARMY/ARO. The Government has certain rights in this invention.

### BACKGROUND OF THE INVENTION

### 1. Field of the Invention

The present invention relates to methods and apparatuses implementing VCSELs.

### 2. Description of the Related Art.

(Note: This application references a number of different publications as indicated throughout the specification by one or more reference numbers in superscripts, e.g., ^{x}. A list of these different publications ordered according to these reference numbers can be found below in the section entitled “References,” Each of these publications is incorporated by reference herein.

Conventional sensing apparatuses, white light sources, and data communications systems have limitations as described herein. For example, conventional data communication systems require separate polarizers and conventional sensing apparatuses have limited resolution.

### SUMMARY OF THE INVENTION

To overcome the limitations in the prior art described above, and to overcome other limitations that will become apparent upon reading and understanding this specification, the present invention discloses the following implementations of a VCSEL.

In a first embodiment, a III-Nitride surface emitting laser is used as the stimulation source for a fluorescent sample in a sensor/instrument. Various embodiments include the surface emitting laser emitting a small circular spot size (˜<4 micrometers), independently or with external lenses, wherein the small spot size allows for unprecedented resolution in a sensor of this type. Example sensors include, but are not limited to, opto-genetic biosensors. Additionally, in various examples, the two dimensional (2-D) array capabilities of sensor embodiments described herein allow for stimulation of multiple points of a sample at once, giving information on the interactions between spatially separated areas of the sample. In various embodiments, the surface emitting lasers have low threshold currents, which means that the array can be battery powered if desired.

A second embodiment is directed to an illumination system. Commonly for semiconductor devices, “white” light is formed by exciting a phosphor with a blue or violet light. Often blue light will be used with a yellow phosphor, and violet with a red-green-blue (RGB) phosphor. The RGB phosphor absorbs all of the violet light and re-emits white light. Embodiments of the second embodiment fabricate of a white light source through the horizontal deposition or placement of a RGB phosphor film or plate on or above a violet III-Nitride Vertical Cavity Surface Emitting Laser (VCSEL) or VCSEL array. Horizontal refers to the phosphor film or plate being parallel to the substrate or submount and perpendicular to the VCSEL output beam.

A third embodiment is directed to a communications system. Currently Vertical Cavity Surface Emitting Lasers (VCSELs) are the predominant light source for data communication. However, increasing the system capacity of communication networks using polarization-division multiplexing requires a polarization stable light source and typical VCSELs require extra processing to become polarization stable. The third embodiment discloses the use of an m-plane or semi-polar III-Nitride VCSEL or VCSEL array for data communication. The data communication takes advantage of the inherent polarization of the VCSELs fabricated on specific crystallographic orientations (m-plane and semi-polar orientations).

### BRIEF DESCRIPTION OF THE DRAWINGS

Referring now to the drawings in which like reference numbers represent corresponding parts throughout:

FIGS. 1A-1B show an example process flow for thermal reflow without VCSELs or pillars (FIG. 1A) and with pillars covering the VCSELs (FIG. 1B) for longer focal length lenses, according to one or more embodiments of the present invention. The pillars are formed through standard lithographic methods with a photoresist that has a higher thermal stability than that of the lens material.

FIG. 2 is a schematic showing the cross section of an example VCSEL array with a deposited transparent layer, according to one or more embodiments of the present invention. A microlens array is etched into the transparent layer for collimating or focusing the VCSEL beams.

FIG. 3 shows a schematic cross section of a single VCSEL device flip-chip bonded to a submount, according to one or more embodiments of the present invention. This image displays a metal thermo-compression bond, however wafer fusion bonding could also be used. Light is extracted through a collimating or focusing microlens etched into the submount. The microlens does not necessarily need to be on the far side of the submount, but there is potential for it to be etched on the same side as the VCSEL. The specific device structure is not shown, only the location of the p-type and n-type GaN are displayed to illustrate that the device structure is “up-side down”. The p-type GaN is not required to have been grown at the top of the device structure.

FIG. 4 illustrates a sensing apparatus, according to one or more embodiments of the present invention.

FIG. 5 is a flowchart illustrating a method of fabricating a sensing apparatus, according to one or more embodiments of the present invention.

FIG. 6 is a flowchart illustrating a method of sensing, according to one or more embodiments of the present invention.

FIG. 7A is a schematic of a LED surrounded by a matrix of RGB phosphor in silicone⁵.

FIGS. 8A and 8B are schematic of the reflective method (FIG. 8A) and the transmission method (FIG. 8B) of white laser-based illumination.

FIGS. 9A-9B illustrate cross section of the phosphor plate on (FIG. 9A) or above (FIG. 9B) the VCSEL array, according to one or more embodiments of the present invention. In FIG. 9A, the phosphor plate has been attached through the use of a transparent epoxy. This is merely an example of one way such a plate could be attached. In FIG. 9B the plate is attached to the packaging device for the VCSEL array and is being held above the VCSEL array.

FIG. 10 shows the phosphor has been deposited as a thick film over the VCSEL array before curing, according to one or more embodiments of the present invention. An effective cooling method would be required for this approach.

FIG. 11 is a flowchart illustrating a method of making a white light source, according to one or more embodiments of the present invention.

FIG. 12 illustrates an example VCSEL structure that can be used for individual VCSELs or the VCSELs in the array, according to one or more embodiments of the present invention.

FIG. 13 illustrates the x plane polarized input beam is modulated 90 degrees to be y plane polarized by passing through an electro-optic crystal. The degree of polarization shift is determined by the voltage applied across the crystal.

FIG. 14 illustrates four channels multiplexed using a PPDM-4 scheme, according to one or more embodiments of the present invention.

FIG. 15 is a flowchart illustrating a method of fabricating a data communications link, according to one or more embodiments of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

### I. First Embodiment: III-Nitride Surface-Emitting Laser Fluorescent Sensor

### 1. Introduction

Various light sources have been developed for use in fluorescent sensors, such as light emitting diodes, Light Emitting Diodes (LEDs), xenon arc lamps, mercury-vapor lamps, halogen bulbs, and lasers. Aside from the lasers, these light sources require filters and other optical modulators to obtain the desired wavelength in a small enough spot size for probing. Lasers provide coherent, relatively small spot size light sources with narrow spectral widths which may not require the additional elements. This could significantly decrease the cost and size of a fluorescent sensor. Vertical cavity surface emitting lasers (VCSELs) have a number of qualities that make them especially desirable, such as circular beam profile, small spot size, low threshold current, and 2D array capabilities¹. The circular beam profile allows for focusing of the beam to even smaller spot sizes, potentially increasing resolution. VCSELs emitting in the infrared (IR) and red bands of the spectrum have been thoroughly tested, however there are many samples that are only excited by shorter wavelengths². Thus far, probes for these types of samples have not experienced the advantages VCSELs have to offer due to light source wavelength limitations. The present invention satisfies this need.

The first embodiment describes the use of III-Nitride VCSELs as the illumination source for sensing applications of a fluorescent sample. In various examples, a VCSEL or VCSEL array can be positioned such that the light output illuminates a certain portion of the sample, the incident beam is absorbed by the sample, and light of a different wavelength is re-emitted. In various examples, as the sample fluoresces, the remaining laser light is filtered out before the detector. After recording, a digital image can be formed.

Various examples can use a matrix bonded or individually addressable array allowing one or multiple VCSELs to lase concurrently. Thus, in one or more examples, the array capabilities of VCSELs allow for simultaneous stimulation of spatially separated sections of the sample. When two or more spots of the sample are stimulated, the progression and interaction of their responses can be recorded to obtain increased information. In one or more examples, using external optics or a form of microlenses allows the VCSEL spot size to be reduced to 4 μm or down to diffraction limited conditions as needed.

In yet further examples, the low threshold current of a VCSEL allows for a VCSEL, or VCSEL array to be powered by battery. This provides the opportunity for the entire sensor system to be battery powered, increasing the potential portability and cost efficiency.

### 2. Lens Fabrication Examples for Optical Manipulation Examples

In some example applications requiring very small spot sizes, the natural VCSEL, beam profile is not sufficiently narrow and external optics are required to adjust the light output. This optical manipulation can be achieved by using a refractive microlens, a Fresnel-like microlens, or a diffractive lens, for example.

In one or more embodiments illustrated herein, a refractive lens or microlens array is used to collimate or focus the light from a VCSEL array. Multiple approaches were considered for testing. A single lens can be used to image the VCSEL array onto the sample. Microlenses have been used to good effect on GaAs VCSEL arrays and on GaN LEDs^{3,4}. To produce these lens arrays, a fabrication technique that allows control of the lens thickness, diameter, and focal length is needed. Three methods are discussed below: polymer lens addition to the surface of the devices (Type I), an external lens array bonded to the surface of the VCSEL array (Type II), and lenses etched on the devices themselves (Type III).

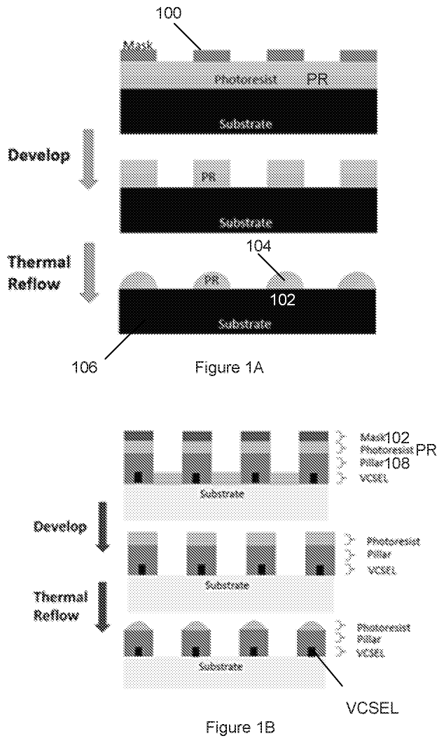

In one or more examples, Type I lenses are generally applied using local dispensing methods or using thermal reflow. Thermal reflow involves depositing photoresist (PR) on a VCSEL array, patterning the PR with a mask 100 so as to remove the PR from everywhere besides above the aperture 102, and melting the resulting cylinders to form hemispherical lenses 104 as shown in FIG. 1A. Depending on the focal length of the resulting lens, pillars 108 of transparent material may be required as shown in FIG. 1B. In one or more embodiments, the first Type I method for microlens array production consists/comprises thermally reflowing a photoresist on or above the substrate 106 comprising the n-side distributed bragg reflector (DBR) of the VCSEL. Photoresist lenses can also be very useful in patterning other materials with better physical properties. They have been used with ion milling and dry etching to produce three dimensional (3-D) profiles of both concave and convex lens design^{5,6}. The Type II method allows for the production of microlenses in other materials, such as fused silica, that can be bonded to the VCSEL array for beam modification. In one or more examples of the Type II method⁷, a hybrid assembly of glass or plastic lenslets is flip chip bonded to the VCSEL array using a UV curable epoxy. The lens material and epoxy are chosen to have a high transmittance at the wavelength of interest and have a coefficient of thermal expansion similar to that of the VCSEL.

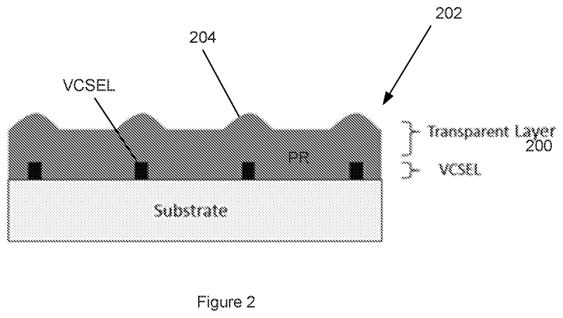

Type III lenses refer to microlenses etched into the devices themselves. Similar to the production of the external lens arrays in Type II, PR lens masks in combination with etching create three dimensional (3-D) patterns in the underlying material. In one case, the PR lenses are fabricated on the top of the device, allowing the lens to be integrated without the need of flip chip bonding an additional layer. The lens may also be etched directly into the DBR of the VCSEL. As an alternative to directly etching into the device, a thick transparent layer 200 can be deposited on the array of VCSELs to provide a surface for etching as shown in FIG. 2. Such a layer can achieved using SU-8 base layers, and could result in reduced packaging costs⁸.

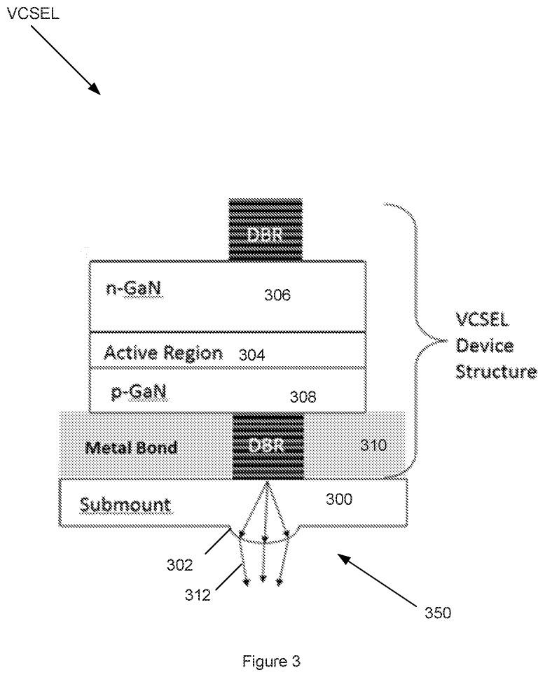

FIG. 3 illustrates the VCSEL can be flip chip bonded to a transparent submount 300 containing etched microlenses 302. The VCSEL of FIG. 3 comprises an active region 304 between n-type III-nitride 306 comprising n-type GaN (n-GaN) and p-type III-nitride 308 comprising p-type GaN (p-GaN). Also shown is a metal bonding layer 310 for bonding the VCSEL structure to the submount 300, DBR mirrors defining the cavity of the VCSEL, and trajectories of the electromagnetic radiation 312 emitted from the active region 304 of the VCSEL.

The above examples are not meant to be an exhaustive list of microlens fabrication techniques compatible with the sensing apparatus of the present invention, but rather provide multiple illustrations of the broad compatibility of the first embodiment of present invention,

### 3. Sensing Apparatus According to One or More Examples

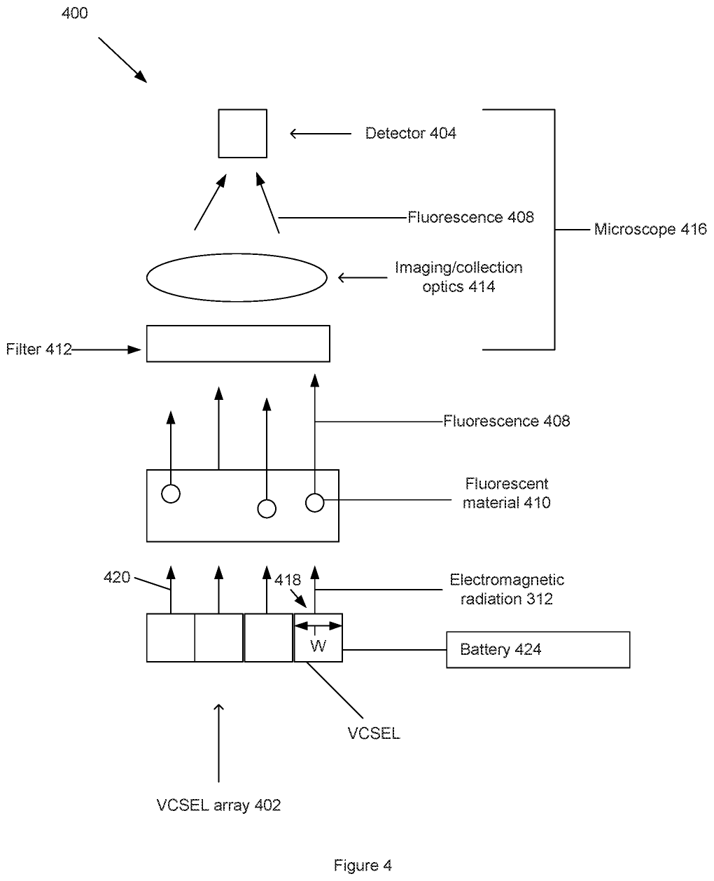

FIG. 4 illustrates an apparatus 400 comprising a VCSEL or VCSEL array 402 emitting electromagnetic radiation 312 having a wavelength in a violet or blue wavelength range; and a detector 404 positioned to detect fluorescence 408 emitted from at least one fluorescent material 410 in response to the VCSEL or the VCSEL array 402 stimulating the at least one fluorescent material 410 with the electromagnetic radiation 312. The apparatus further includes a filter 412, imaging or collection optics 414, and a microscope 416 (wherein the microscope includes the detector 404, the filter 412, and the optics 414).

The following describes an example sensing apparatus comprising an opto-genetic probe that may provide unparalleled resolution for imaging real time synaptic activity. Neurons are optogenetically tagged with fluorescent material 410 comprising fluorescent protein, such as (but not limited to) pHlourin2, to illuminate when probed with violet or blue light (the pHlourin2 protein has an emission wavelength of 509 nm⁹). The neurons are placed in the focal plane of a microscope 416 having a 490 nm long-pass wavelength filter 412 below the objective lens (e.g., collection optics 414) to attenuate any light from the illumination source (e.g., VCSEL or VCSEL array 402. In one or more examples, the array 402 comprises an individually addressable III-Nitride non-polar VCSEL laser array emitting at 405 nm wavelength light and further including an optical element (e.g., lens) so as to emit a diffraction limited spot size. In one or more examples, the laser array 402 is further packaged and connected to an external controller before being placed directly below the transparent container of neurons. In addition, or alternatively, the VCSEL array 402 can be coupled to optical fibers to transmit the light to the sample. In various example implementations, the laser light is used to excite specific areas of the neural network, and fluorescence 408 from the different areas is detected with the fluorescence microscope 416. As the electrical impulses travel through the synapses, the sample may continue to fluoresce with the traveling electrical signals. Thus, an individually addressable array of VCSELs allows stimulation of multiple neurons simultaneously, which can yield important information about the way neurons interact.

The device example illustrated herein is merely for illustration purposes and is not intended to represent the limit of applicability or scope of the sensing embodiment described herein. III-N VCSEL illumination of fluorescent matter is relevant for many other applications and types of sensors.

The III-N surface emitting array with microlenses can also be used for imaging neurons.

### 4. Process Steps

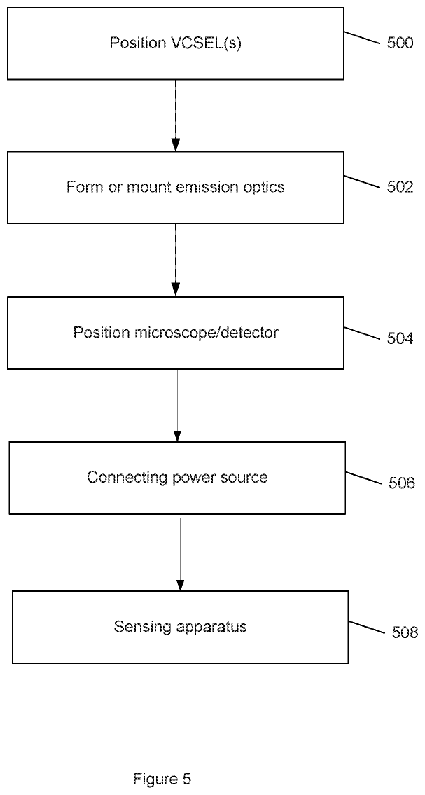

FIG. 5A is a flowchart illustrating a method of fabricating an apparatus.

Block 500 represents positioning/obtaining a VCSEL or VCSEL array emitting electromagnetic radiation. In one or more examples, the electromagnetic radiation has a wavelength in a violet or blue wavelength range. The VCSEL may comprise a plurality of VCSELs, e.g., disposed in rows and columns, e.g., in two dimensions.

In one or more embodiments, the VCSEL or VCSEL array comprises (e.g., non-polar or semi-polar) III-Nitride material.

Block 502 represents optionally forming or mounting emission optics. The step comprises forming a microlens array or lens on or above the VCSEL, the VCSEL array, or each of a plurality of VCSELs in the VCSEL array. In one or more embodiments, the microlens is etched into the III-Nitride material of the VCSEL, the III-Nitride material of the VCSEL array, or the III-Nitride material of each of the plurality of the VCSELs in the VCSEL, array. In other embodiments, the step comprises patterning photoresist on the VCSEL or on each of the plurality of the VCSELs in the VCSEL array so that the microlens or lens comprises the patterned photoresist.

Block 504 represents positioning a detector system (e.g., microscope) to detect fluorescence emitted from at least one fluorescent material in response to the VCSEL or the VCSEL array stimulating the fluorescent material(s) with the electromagnetic radiation.

Block 506 represents connecting a power source. In one or more examples, a battery powers the VCSEL or the VCSEL array.

Block 508 illustrates the end result, a sensing apparatus 400, e.g., as illustrated in FIG. 4.

The apparatus can be embodied in many ways including, but not limited to, the following.

1. An apparatus 400 comprising a VCSEL or VCSEL array 402 emitting electromagnetic radiation 312. having a wavelength in a violet or blue wavelength range; and a detector 404 positioned to detect fluorescence 408 emitted from at least one fluorescent material 410 in response to the VCSEL or the VCSEL array 402 stimulating the at least one fluorescent material 410 with the electromagnetic radiation 312.

2. The apparatus of embodiment 1, wherein each of a plurality of the VCSELs are spaced in the array 402 and have an optical aperture 418 with a width W emitting a beam 420 of the electromagnetic radiation 312, each of the beams 420 stimulate different parts of the fluorescent material 410 or a plurality of the fluorescent materials 410 that are spatially separated, and the fluorescence 408 emitted from the different parts or from the plurality of the fluorescent materials 410 is used to measure interactions in the fluorescent material 410 or between the fluorescent materials or between materials e.g., neurons) connected to the fluorescent materials 410.

3. The apparatus of embodiments 1 or 2, wherein the VCSEL or VCSEL array 402 comprises a non-polar or semi-polar 111-Nitride material.

4. The apparatus of one or any combination of the previous embodiments, wherein the apparatus 400 is an optogenetic sensor.

5. The apparatus of one or any combination of the previous embodiments, wherein the apparatus comprises an optogenetic probe wherein the fluorescent material 410 comprises a protein attached to a neuron, the protein fluoresces/emits when the neuron is stimulated. The emission/fluorescence 408 emitted from the fluorescent material (protein) contains information used to measure and/or characterize interactions of the neurons.

6. The apparatus of one or any combination of the previous examples, wherein the fluorescent material 410, or each of the fluorescent materials 410, comprise a neuron individually addressed by one or more of the VCSELs (e.g., in the array of VCSELs).

7. The apparatus of embodiments 5 or 6, wherein the neuron is a single neuron stimulated by multiple VCSELs, or a single VCSEL may stimulate multiple neurons if the neurons are overlapping.

8. The apparatus of one or any combination of the previous examples, wherein the VCSEL or each of a plurality of the VCSELs in the array 402 irradiate the at least one fluorescent material with a beam 420 having a diameter less than 4 micrometers.

9. The apparatus of one or any combination of the previous examples, further comprising a battery 424 powering the VCSEL or the VCSEL array.

10. The apparatus of one or any combination of the previous examples, further comprising a microlens array 202 or lens 302 on or above the VCSEL, the VCSEL, array 402, or each of a plurality of VCSELs in the VCSEL array 402. In one example, the microlens array 202 is on or coupled to the VCSEL array 402. In one or more examples, a different lens is coupled to or on or above each of the VCSELs in the array 402.

11. The apparatus of embodiment 10, wherein the lens (e.g., a microlens) is etched into the III-Nitride material of the VCSEL, the III-Nitride material of the VCSEL array 402, or the III-Nitride material of each of the plurality of the VCSELs in the VCSEL array.

12. The apparatus of embodiment 10, wherein the lens 204 (e.g., microlens) comprises photoresist PR patterned on the VCSEL or on each of the plurality of the VCSELs in the VCSEL array 402.

13. The apparatus of embodiment 10, further comprising an external microlens array 350 including a plurality of microlenses 302., wherein the external microlens array 350 is bonded to the VCSEL or VCSEL array.

14. The apparatus of one or any combination of embodiments 10-13, wherein the lens or microlens has a diameter in a range of 1 micron to 1000 microns.

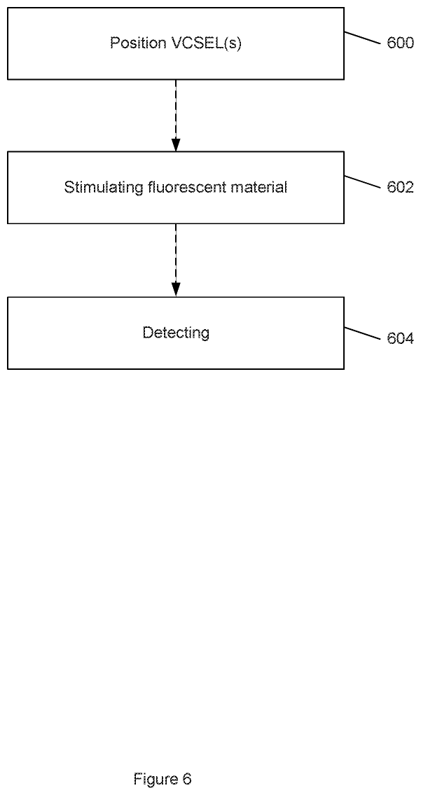

FIG. 6 is a flowchart illustrating a method of sensing, comprising using/positioning a VCSEL or VCSEL array emitting in the violet or blue wavelength range in conjunction with a sample, as illustrated in Block 600, and wherein the VCSEL or VCSEL array stimulates fluorescent material in the sample (Block 602) and the resulting illumination is detected (Block 604).

The method can be embodied in many ways including, but not limited to, the following.

1. The method of sensing using the apparatus described in Block 508 above.

2. The method wherein the VCSEL or VCSEL array comprises non-polar or semipolar III-N material.

3. The method of one or any combination of the previous embodiments, wherein the VCSEL array stimulates multiple parts of the sample.

4. The method of one or any combination of the previous embodiments, wherein the VCSEL or the VCSEL array are battery powered.

5. The method of one or any combination of the previous embodiments, further comprising a microlens array or lens on or above the VCSEL or VCSEL array.

### 5. Advantages and Improvements

III-Nitride VCSELs represent a new forefront of semiconductor laser research that would allow samples that are excited by near-UV or blue light to be tested. These laser devices emit in the ultraviolet (UV) and visible spectrum normal to their surface promoting their use in many novel applications.

Novelties of the present invention include, but are not limited to, a small circular spot size emitted by the VCSEL(s) and array capabilities allowing imaging of interactions. As a result, sensors produced with the components according to embodiments described herein can provide unprecedented resolution and sensing capabilities and allow for a competitive advantage through vertical differentiation. In conventional devices, the resolution is not as high and as such small phenomena may not me noticed.

Secondly, conventional sensors often require bulky power sources for operation. The novel use of III-N VCSEL array in the sensor according to embodiments described herein, on the other hand, enables battery power to be used and makes the instrument more ergonomic and easier to transport.

### 6. References for the First Embodiment

The following references are incorporated by reference herein.

1. Leonard, J. T. et al. Nonpolar III-nitride vertical-cavity surface-emitting laser with a photoelectrochemically etched air-gap aperture. Appl. Phys. Lett. 108, 031111 (2016).

2. Redding, B., Bromberg, Y., Choma, M. A. & Cao, H. Full-field interferometric confocal microscopy using a VCSEL array. Opt. Led. 39, 4446-4449 (2014).

3. Kim, D., Lee, H., Cho, N., Sung, Y. & Yeom, G. Effect of GaN Microlens Array on Efficiency of GaN-Based Blue-Light-Emitting Diodes. Jpn. J. Appl. Phys. 44, L18 (2004).

4. Bardinal, V. et al. Collective Micro-Optics Technologies for VCSEL Photonic Integration. Adv. Opt. Technol. 2011, e609643 (2011).

5. Gratrix, E. J. Evolution of a microlens surface under etching conditions. in 1992, 266-274 (1993).

6. Stern, M. B. & Rubico Jay, T. Dry etching: path to coherent refractive microlens arrays. in 1992, 283-292 (1993).

7. Moench, H. et al. VCSEL arrays with integrated optics. in 8639, 86390M-86390M-10 (2013).

8. Levallois, C. et al. VCSEL collimation using self-aligned integrated polymer microlenses. in 6992, 69920W-69920W-8 (2008).

9. Mahon. M. J. pHluorin2: an enhanced, ratiometric, pH-sensitive green florescent protein. Adv. Biosci. Biotechnol. Print 2, 132-137 (2011).

### II. Second Embodiment: III-Nitride Vertical Cavity Surface Emitting Laser (VCSEL) White Light Illumination System

### 1. Introduction

Light Emitting Diode (LED) lighting was made possible by Nakamura et al. when the first double heterostructure blue LED was produced¹. White LEDs, consisting of a blue LED covered by a yellow phosphor (YAG:Ce), were commercialized shortly after in 1996². LEDs as a lighting source have gained prevalence since their inception, and are expected by some to become the primary light source in the future³.

Traditionally, for solid state lighting, a blue or near-UV LED is used to excite a phosphor which converts all or part of the incident illumination to a longer wavelength, as shown in FIG. 1⁴. Often blue light will be used with a yellow phosphor, and violet light is used with a red-green-blue (RGB) phosphor. Commonly, the RGB phosphor absorbs all of the violet light and re-emits white light, whereas the yellow phosphor allows a certain percentage of the blue light to remain unaltered and mix with the emitted yellow, The RGB phosphor is generally needed for a better approximation of standard white light⁵. However, these LEDs experience droop (a loss of efficiency at high currents) limiting their maximum output power. This, in conjunction with thermal effects, leads to an overall decrease in efficiency and a change in the color point of the white light when pumped hard⁶.

Thus, LEDs have some limitations that provide a market space for other light sources, such as laser diodes. Laser diodes do not suffer from this efficiency loss and offer an appealing alternative for high powered or directional lighting solutions⁷.

### 2. Example Systems

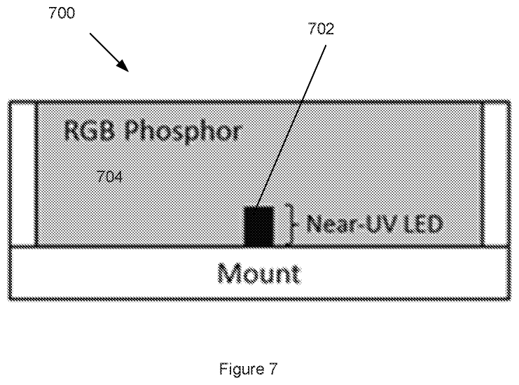

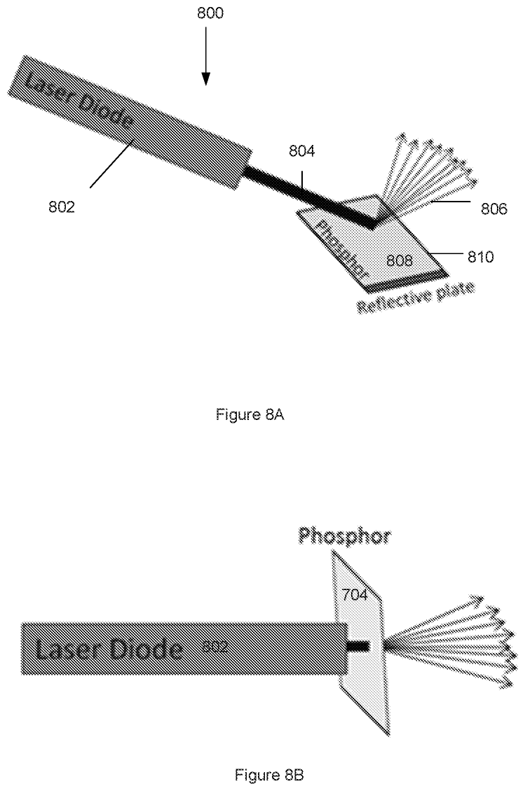

Edge emitting lasers have been coupled with phosphors both for lighting and testing visible light communication^{6,8-12}. FIGS. 7 and 8A-8B illustrate the transmission and reflective methods. The transmission method is characterized by an apparatus 700 comprising (e.g., a light source such as a near UV LED 702) shining light 706 through a red-green-blue (RGB) phosphor plate 704 placed at the emitting end of the light source 702. FIG. 8B shows the transmission method using a laser diode 802. The reflective method consists of an apparatus 800 including a laser diode 802 emitting electromagnetic radiation 804 and the electromagnetic radiation 804 being reflected off 806 of a phosphor 808 covered reflective surface 810 or plate¹³. In both cases, the use of a near-UV light source and RGB phosphor generally leads to total attenuation of the near-UV beam. This is advantageous as it can eliminate the safety concerns associated with laser light and eyes. Additionally, there is variability in the possible color temperatures through customization of the RGB phosphor.

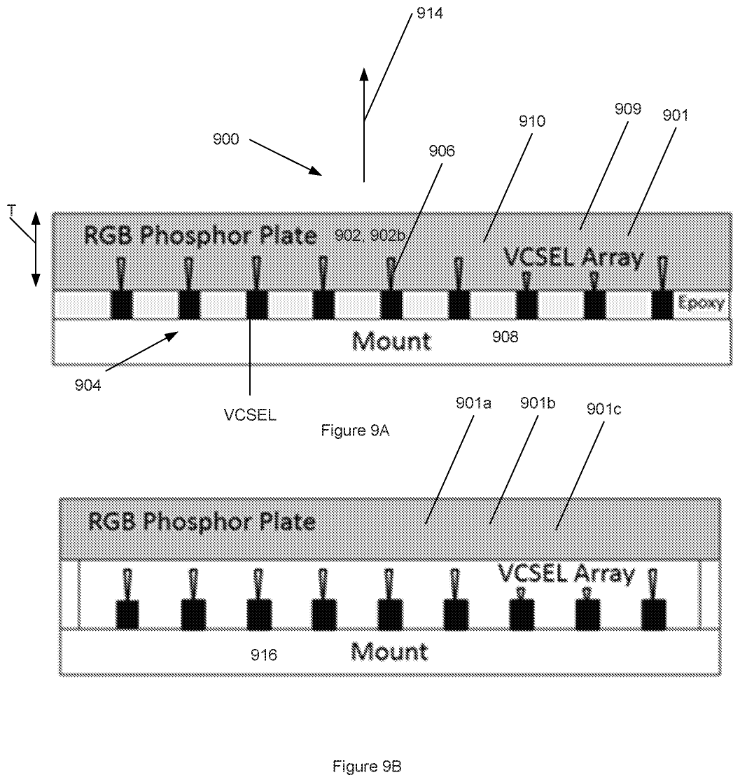

Another laser structure of interest is the vertical cavity surface emitting laser (VCSEL) which has on-chip two dimensional (2-D) array capabilities¹⁴. FIGS. 9A and 9B illustrate embodiments of the present invention comprising a white light source or illumination system 900 fabricated through the horizontal deposition or placement of a phosphor 901 (e.g., RGB phosphor film or plate 902) on or above a near-UV III-Nitride VCSEL or VCSEL array 904. Also shown in FIGS. 9A-9B are the VCSELs in the array 904, the electromagnetic radiation 906 emitted from the VCSELs, the mount 908 on which the VCSELs are mounted, and the white light 914 emitted from the white light illumination system 900.

VCSELs can replace LEDs in many lighting applications due to their smaller size and higher power. In one or more embodiments, the VCSELs are fabricated in two dimensional (2-D) arrays, allowing on chip testing and the opportunity for simple packaging with a phosphor. Being able to simply place the phosphor on or above the VCSEL array significantly simplifies the processing and enhances final device stability.

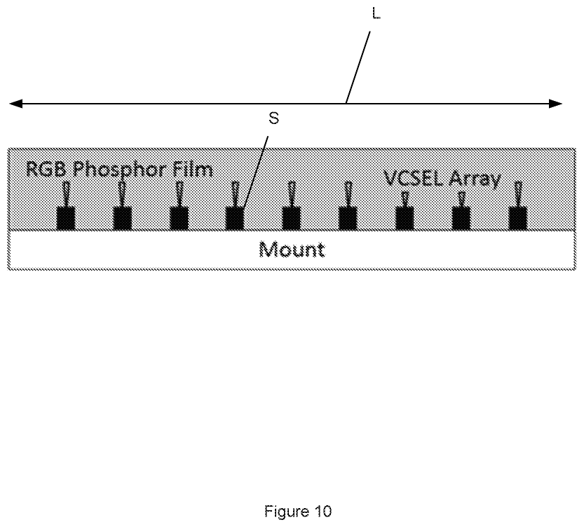

In one embodiment, a RGB phosphor powder 909 is mixed with a resin 910 (e.g., silicone resin). To form a plate 902, the resin 910 can be molded and cured. This plate can then be mounted on or above a VCSEL array as shown in FIGS. 9A-9B. FIG. 10 illustrates an example wherein the resin is placed on the VCSEL array before curing, such that the resin is attached to the chip. The phosphor can then be cured once its shape is as desired.

In various examples, the thickness of phosphor above the VCSEL is calibrated such that all of the violet light emitted from the VCSELs is absorbed, but the absorption is not unduly large.

In various examples, for thermal management, the bottom of the VCSEL array is attached to a heatsink.

An alternative to a powder-in-silicone phosphor comprises a ceramic or single crystal phosphor plate. A ceramic or single crystal phosphor plate lends itself to the fabrication methods shown in FIGS. 9A-9B. The advantages of this method include the significantly larger thermal conductivity of the phosphor, increased mechanical stability, and potentially reduced scattering and absorption¹⁵. The higher thermal conductivity is especially important with high luminance point-like sources, such as VCSELs, where insufficient heat transport can lead to lower efficiency and browning of a matrix material. However, using ceramic or single crystal phosphors can, in some examples, increase the capital requirements for production.

### 3. Process Steps

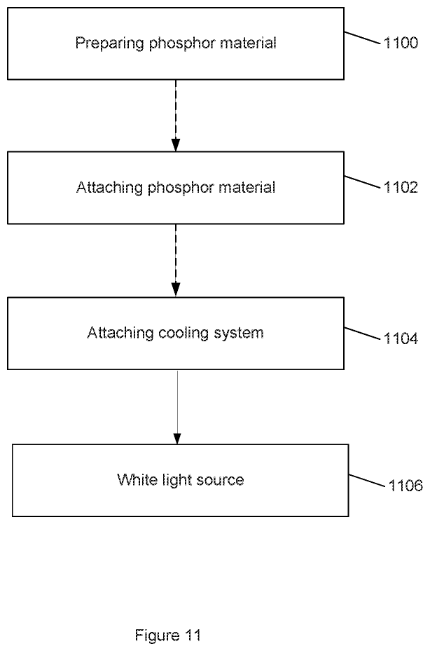

FIG. 11 illustrates a method of making a white light illumination system.

Block 1100 represents optionally preparing/obtaining the phosphor material.

In one or more embodiments, the step comprises combining together a red phosphor material, a green phosphor material, and a blue phosphor material so as to form a phosphor combination.

The phosphor materials may comprise single crystal phosphors, ceramics, or phosphors combined with a resin. The phosphor materials may comprise, or be combined so as to form, a plate 902 or a film 902b. In one or more embodiments, the red phosphor material, the green phosphor material, and the blue phosphor material may be distributed throughout the plate or the film.

In one or more embodiments, the resin is combined with the phosphor and then molded and cured prior to deposition on the VCSEL/VCSEL array.

Block 1102 represents depositing the phosphor horizontally on or above a III-Nitride VCSEL or VCSEL array. The array may comprise a plurality of VCSELs, e.g., disposed in two dimensions, e.g., in rows and columns.

In one or more embodiments, the step comprises attaching or mounting (e.g., bonding or gluing) the film 902b or the plate 902 to the VCSEL, array 904, wherein the plate 902 or the film 902b includes the phosphor 901 covering a plurality of the VCSELs in the array and a thickness of the plate or film is less than a length of the film or the plate extending across the VCSEL array.

In or more embodiments including a resin, the resin is molded and cured after the phosphor and resin are deposited on the VCSEL array.

Block 1104 represents optionally depositing/attaching a cooling system 916 below the VCSEL array, so that the VCSEL array is between the phosphor and the cooling system and in thermal contact with the cooling system.

Block 1106 represents the end result, a white light source or illumination system 900.

The white light illumination system can be embodied in many ways including, but not limited to, the following (referring to FIGS. 9A, 9B, and 10).

1. The white light illumination system 900 including a phosphor 901 horizontally on or above a VCSEL or VCSEL array 904. White light 914 is emitted from the phosphor 901 in response to electromagnetic radiation 906 (e.g., comprising one or more blue and/or violet wavelengths) emitted from the VCSEL(s) being absorbed in the phosphor 901 or optically pumping the phosphor 901.

2. The white light illumination system 900 comprising a film 902b or plate 902 attached to VCSEL array, wherein the plate 902 or the film 902b includes the phosphor 901 covering a plurality of the VCSELs in the array 904, a thickness T of the plate 902 or film 902b is less than a length L of the film 902b or the plate 902 extending across a surface S of the VCSEL array 904, and white light 914 is emitted from the phosphor 901 in response to electromagnetic radiation 906 emitted from the VCSELs being absorbed in the phosphor 901.

3. The system of embodiments 1 or 2 wherein the phosphor 901 comprises a red phosphor material 901a emitting red light in response to red phosphor material absorbing and/or scattering the electromagnetic radiation 906, a green phosphor material 901b emitting green light in response to the green phosphor material absorbing and/or scattering the electromagnetic radiation 906, a blue phosphor material 901c emitting blue light in response to the blue phosphor material absorbing and/or scattering the electromagnetic radiation 906; and a combination of the blue light, red light, and green light is viewed as the white light 914.

4. The system of embodiment 3, wherein the electromagnetic radiation 906 from each of the VCSELs is absorbed by (and/or optically pumps) the red phosphor material 901a, the green phosphor material 901b, and the blue phosphor material 901c.

5. The system of embodiment 3 or 4, wherein the red phosphor material 901a, the green phosphor material 901b, and the blue phosphor material 901c are distributed throughout the plate 902 or the film 902b.

6. The system 900 of one or any combination of the previous embodiments, wherein the phosphor 901 comprises a single crystal phosphor or a ceramic phosphor.

7. The system of one or any combination of the previous embodiments, wherein the phosphor 901 is combined with a resin 910.

8. The system of one or any combination of the previous embodiments, further comprising a cooling system 916 below the VCSEL array, wherein the VCSEL array 904 is between the phosphor 901 and the cooling system 916.

9. The system of one or any combination of the previous embodiments, wherein an emission wavelength of the electromagnetic radiation 906 emitted from III-N VCSEL or VCSEL array 904 is in a violet or blue wavelength range.

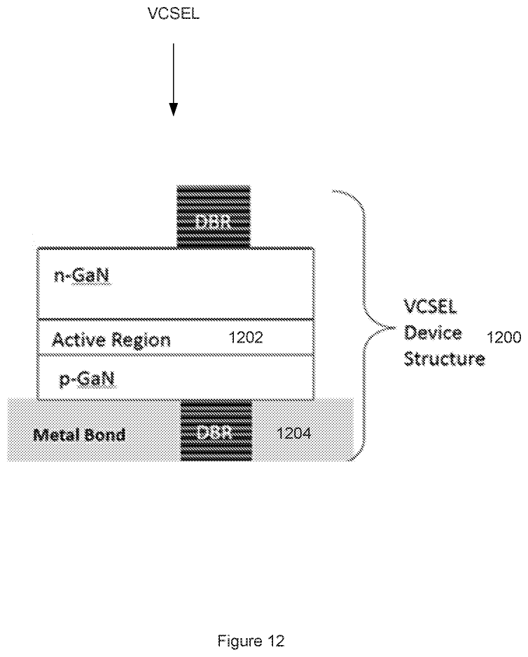

FIG. 12 illustrates an example VCSEL structure 1200 used for individual VCSELs or the VCSELs in the array 904. The VCSEL structure comprises an active region 1202 between an n-type III-nitride layer e.g., n-type GaN (n-GaN) and a p-type III-nitride layer, e.g., p-type GaN (p-GaN). DBRs define the optical cavity of the VCSEL and the VCSEL structure is mounted to a mount using a metal bond 1204.

### 4. Advantages and Improvements

LEDs suffer from a loss of efficiency at high current densities and do not have inherent directionality. Lasers allow much higher powers to be reached per area and produce very directional light. For applications where bright directional light is needed, lasers have a much higher efficiency in terms of light per power per area of the desired surface illuminated when the surface is more than a few meters away.

One or more embodiments illustrated herein describe the fabrication of a white light source comprising a phosphor horizontally on or above a VCSEL array. Novel aspects of the invention include, but are not limited to, the horizontal orientation of a red-green-blue (RUB) phosphor in relation to the substrate or submount, in conjunction with the VCSEL, array (e.g., emitting violet light) for white light generation. VCSELs with a. horizontal phosphor offer easy assembly and simple manufacturability.

### 5. References for the Second Embodiment

The following references are incorporated by reference herein.

1. P-GaN/N-InGaN/N-GaN Double-Heterostructure Blue-Light-Emitting Diodes. Jpn. J. Appl. Phys. 32, L8 (1993).

2. Bando, K., Sakano, K., Noguchi, Y. &. Shimizu, Y. Development of High-bright and Pure-white LED Lamps. J. Light Vis. Environ. 22, 1_2-1_5 (1998).

3. Why people still use inefficient incandescent light bulbs. USA TODAY Available at: https://www.usatoday.com/story/news/nation-now/2013/12/27/incandescent-light-bulbs-phaseout-leds/4217009/. (Accessed: 25 Sep. 2017)

4. Camras, M. D, et al. Common optical element for an array of phosphor converted light emitting devices. (2011).

5. Kon, T. & Kusano, T. White LED with Excellent Rendering of Daylight Spectrum. Opt. Photonik 9, 62-65 (2014).

6. Denault, K. A., Cantore, M., Nakamura, S., DenBaars, S. P. & Seshadri, R. Efficient and stable laser-driven white lighting. AIP Adv, 3, 072107 (2013).

7. Abu-Ageel, N. & Aslam, D. Laser-Driven Visible Solid-State Light Source for Etendue-Limited Applications. J. Disp. Technol. 10, 700-703 (2014).

8. Chi, Y.-C. et al. Violet Laser Diode Enables Lighting Communication. Sci. Rep. 7, (2017),

9. Cantore, M. et al. High luminous flux from single crystal phosphor-converted laser-based white lighting system. Opt. Express 24, A215-A221 (2016).

10. Chi, Y.-C. et al. Phosphorous Diffuser Diverged Blue Laser Diode for Indoor Lighting and Communication, Sci. Rep. 5, srcp 8690 (2015).

11. Desault, K. A., DenBaars, S. P. &. Seshadri, R. Laser-driven white lighting system for high-brightness applications. (2015).

12. Kelchner, K. M., Speck, J. S., Pfaff, N. A. & DenBaars, S. P. White light source employing a iii-nitride based laser diode pumping a phosphor. (2014).

13. Laser Lighting: White-light lasers challenge LEDs in directional lighting applications. Available at: http://www.laserfocusworld.com/articles/print/volume-53/issue-02/world-news/laser-lighting-white-light-lasers-challenge-leds-in-directional-lighting-applications.html. (Accessed: 22 Sep. 2017)

14. Haitz, R. H. Vertical cavity surface emitting laser arrays for illumination. (1998).

15. Raukas, M. et al. Ceramic Phosphors for Light Conversion in LEDs. ECS J. Solid State Sci. Technol. 2, 83168-83176 (2013).

### III. Third Embodiment: Polarization-Locked Communication using III-Nitride m-Plane Vertical Cavity Surface Emitting Lasers (VCSELs)

### 1. Introduction

The demand for optical communication network system capacity is ever increasing and requires innovative technological ideas to keep up with these demands. Numerous methods of light modulation have been used to increase the data capacity, such as frequency-division multiplexing, time-division multiplexing, and polarization-division multiplexing (PDM). PDM is a scheme for increasing the system capacity of a data network through supporting two or more independent data streams with differing polarizations¹. Traditionally, the polarization angles were orthogonal to limit crosstalk. However, recently, Chen et al, demonstrated a four state PDM (PPDM-4) scheme that modulated four linearly polarized data sources, all with the same wavelength¹. The signal was successfully transmitted over 150-km through a single mode fiber.

### 2. Example Systems

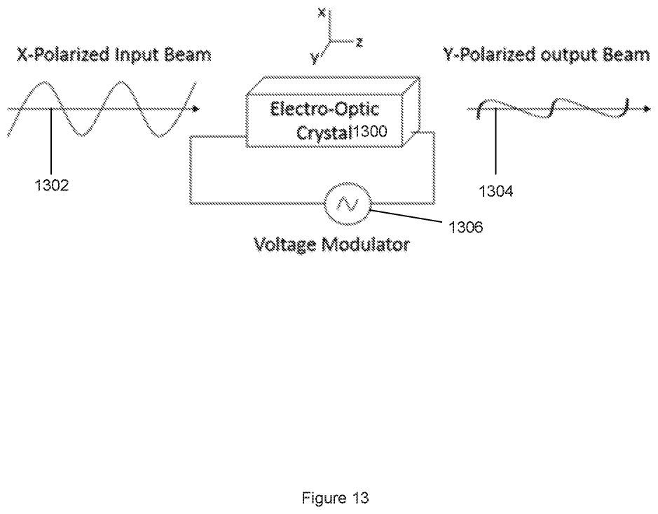

PDM is achieved by using an electro-optic crystal 1300 to modulate the polarization of a data stream, as shown in FIG. 13. The input light 1302 to the modulator 1300 (e.g., electro-optic crystal) needs to be plane polarized (e.g., X-polarized light beam), which is generally achieved (for an unpolarized input²) through the use of a polarizer before the modulator 1300. However, if the light is consistently polarized in a known direction, then the polarizer is not needed. Predominantly, however, conventional light sources (such as a conventional VCSEL) are polarized in a random direction, which can make coupling difficult. An even bigger issue is polarization switching, where the polarization of the output beam changes with some other variable, such as current³. This phenomenon can significantly increase the noise of the device such that the polarization noise exceeds that of the power by 15-20 dB. Minimizing the noise is imperative in high-speed data communication. Additionally, the polarization cannot be controlled by a polarizer inserted in the beam path as may be done elsewhere.

The modulator 1300 outputs a polarized output beam 1304 in response to receiving the input beam 1302 and a voltage applied across the electro-optic crystal 1300 from a voltage modulator 1306.

After much research, polarization control of VCSELs was achieved by using a surface grating on the emitting distributed Bragg Reflector (DBR) to add a polarization dependence for the roundtrip gain. It was found that the grating must have a period significantly less than the wavelength of the emitted beam, such as a 60 nm groove width for an 850 nm emission wavelength⁴. Thus, to control the polarization, extra processing steps are required and extremely fine features are needed. This increases the cost and difficulty of producing a VCSEL. Though this technique has been thoroughly studied in conjunction with GaAs based VCSELs, the technique has yet to reach prominence for any III-Nitride based systems. While III-N devices are the primary light source for visible light communication, III-N VCSELs have not been realized in this capacity yet⁵. Thus far, LEDs account for the majority of industrial light sources, though many of the VCSEL properties make VCSELS a more preferable choice.

### 3. VCSEL Orientation

Due to the hexagonal structure of III-Nitride materials, different crystal planes can be chosen for growth with different properties. The most researched VCSELs have been grown on the c-plane; however in-plane or semipolar planes offer some distinct advantages, such as higher material gain and emission of stable light polarized along the a-direction⁶. Thus, an array of m-plane or semipolar VCSELs are completely polarized in the same direction, unlike c-plane VCSELs where the random polarization direction prevents uniform polarization.

### 4. Data Communication Using m-Plane or Semipolar VCSELs

The present invention discloses the use of an inherently plane polarized m-plane III-Nitride VCSEL (m-VCSEL) or a semipolar-plane ill-Nitride VCSEL (s-VCSEL) for high speed optical communication.

Data communication can be implemented using polarization-division multiplexing, amplitude-shift keying modulation schemes, or other methods requiring polarized light. M-plane VCSELs (M-VCSELs) do not require the polarization stabilizing schemes, such as the addition of a surface grating, for compatibility with polarization sensitive applications, thereby decreasing the cost and complexity of production. Another consideration surfaces when one realizes that the surface grating needs to be significantly smaller than the material wavelength. The material wavelength of visible light n GaN is smaller than that of infrared (IR) wavelengths in the GaAs system, thus the grating features would have to be even smaller than those previously implemented. These fine features further increase the production difficulty for c-plane VCSELs compared to m-plane VCSELs.

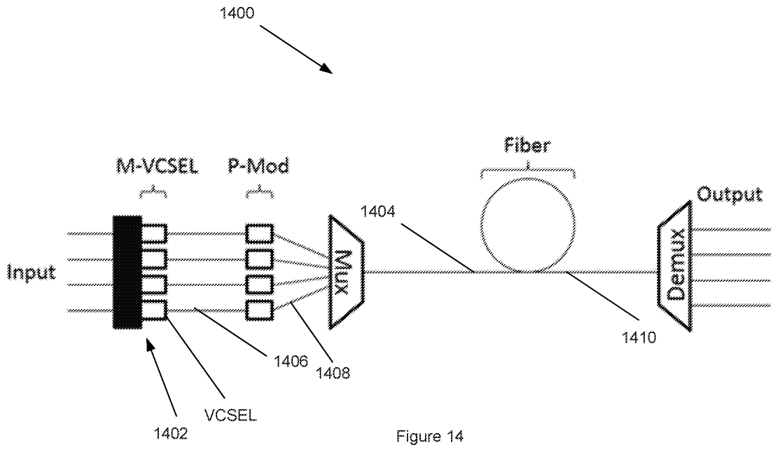

FIG. 14 illustrates an embodiment of the present invention comprising a data communications link 1400 including (e.g., 2×2) individually addressable m-VCSEL array or semipolar-VCSEL array 1402 coupled to four polarization modulators (p-Mod). The p-Mod are connected to a multiplexer (Mux), the modulators p-Mod are coupled to an optical fiber 1404, and the optical fiber connects to a demultiplexer (demux). Each m-VCSEL or semipolar-VCSEL represents a separate data channel that can be carried through the fiber using the PPDM-4 scheme.

### 5. Process Steps

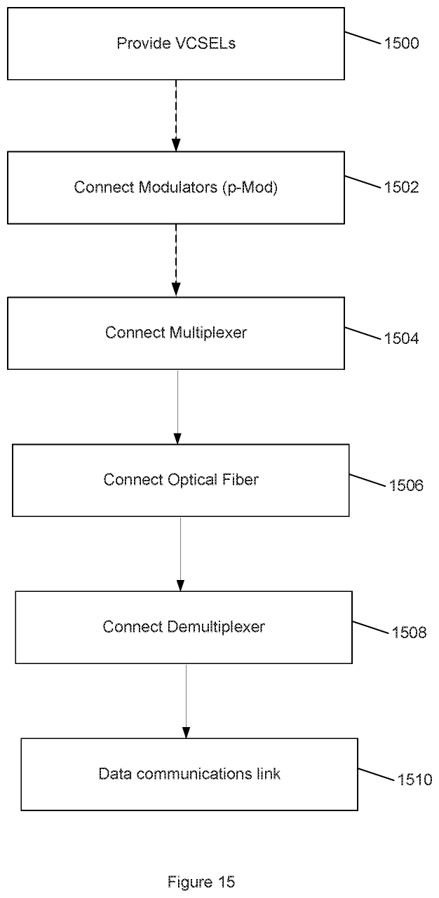

FIG. 15 illustrates a method of fabricating a data communication link.

Block 1500 represents providing an array of HI-Nitride VCSELs each having an m-plane or semipolar plane crystal orientation and emitting polarized electromagnetic radiation. FIG. 12 illustrates an example structure for the VCSELs used in the array. The array may comprise a plurality of VCSELs (e.g., disposed in two dimensions, e.g., in rows and columns, e.g., 2 rows by 2 columns).

In one or more embodiments, the electromagnetic radiation emitted from the VCSELs has a polarization ratio of more than 0.80 along a crystallographic a-direction of the VCSELs. The polarization ratio for radiation having an intensity Ip (that is polarized) and an intensity Iu (that is unpolarized) is defined as Ip/(Ip+Iu).

In one or more embodiments, the electromagnetic radiation has an emission wavelength in a violet, blue, or green wavelength range.

Inputs to each of the VCSELs modulate the electromagnetic radiation emitted from each of the VCSELs with a data stream.

Block 1502 represents optionally connecting a plurality of modulators (p-mods). Each of the modulators are connected to and associated with a different one of the VCSELs and modulate a polarization of the electromagnetic radiation emitted from the one of the VCSELs associated with the modulator. Thus the data link includes a plurality of data channels each transmitting data/a data stream using the electromagnetic radiation/field modulated by a different one of the modulators and transmitted fr©m the VCSEL associated with the modulator. Each of the modulators shift the polarization by different amounts so that the output of each modulator outputs electromagnetic radiation/an electromagnetic field having a different polarization state. In one or more examples, the modulators shift the polarization (comprising a linear polarization) by a number of degrees (e.g., 90 degrees).

Block 1504 represents optionally connecting a multiplexer (mux) to the modulators, wherein the multiplexer multiplexes the modulated electromagnetic radiation/fields (having different polarization states) outputted from each of the modulators. The multiplexer combines the electromagnetic radiation/fields having different polarizations (and data streams carried by the electromagnetic radiation/fields having different polarizations) into a combined signal/multiplexed electromagnetic radiation.

Block 1506 represents optionally connecting an optical fiber to the multiplexer, wherein the optical fiber transmits the multiplexed electromagnetic radiation/combined signal outputted from the multiplexer.

Block 1508 represents optionally connecting a demultiplexer (demux) to the optical fiber, wherein the demultiplexer demultiplexes the multiplexed electromagnetic radiation/combined signal transmitted through the optical fibers. The demultiplexer separates the combined signal into the different polarization components (into the electromagnetic fields/radiation having different polarizations) so that the data streams carried by each of the electromagnetic fields may be read at the outputs.

Block 1510 represents the end result, a data communications link 1400, e.g., as illustrated in FIG. 14.

The data communication link can be embodied in many ways including, but not limited to, the following.

1. A data communication link 1400, comprising an array 1402 of III-Nitride Vertical Cavity Surface Emitting Lasers (VCSELs) each having an in-plane or semipolar plane crystal orientation and emitting polarized electromagnetic radiation 1406.

2. The data communication link of embodiment 1, further comprising a plurality of modulators p-Mod, 1300 wherein each of the modulators are connected to and associated with a different one of the VCSELs and modulate a polarization of the electromagnetic radiation 1406 emitted from the one of the VCSELs associated with the modulator p-mod. The data communications link includes a plurality of data channels each transmitting data using the electromagnetic radiation 1406 modulated by a different one of the modulators p-Mod and transmitted from the VCSEL associated with the modulator p-Mod. Each of the modulators p-Mod output modulated electromagnetic radiation 1408 having a different polarization state (or different polarization) in response to the modulator p-Mod receiving the electromagnetic radiation 1406 inputted from one of the VCSELs.

3. The data communication link of embodiment 2, wherein each of the modulators p-Mod shift the polarization (of the electromagnetic radiation 1406) comprising a linear polarization by a different number of degrees.

4. The data communication link of embodiment 3, further comprising a multiplexer Mux connected to the modulators p-Mod and multiplexing the modulated electromagnetic radiation 1408 outputted from the modulators p-Mod so as to form multiplexed electromagnetic radiation 1410 (e.g., comprising a combination of the modulated electromagnetic radiation 1408 having different polarizations)

5. The data communication link of embodiment 4, further comprising an optical fiber 1404 connected to the multiplexer Mux, wherein the optical fiber 1404 transmits the multiplexed electromagnetic radiation 1410 outputted from the multiplexer Mux in response to the multiplexer Mux receiving the modulated electromagnetic radiation 1408 from the modulators p-Mod.

6. The data communication link 1400 of embodiment 5, further comprising a de-multiplexer (DeMux) connected to the optical fiber 1404, the de-multiplexer de-multiplexing the multiplexed electromagnetic radiation 1410 transmitted through the optical fiber 1404.

7. The data communication link of embodiment 1, wherein the electromagnetic radiation 1406 emitted from the VCSELs has a polarization ratio of more than 0.80 along a crystallographic a-direction of the VCSELs.

8. The data communication link of embodiment 1 comprising VCSELs, modulators (p-Mod), multiplexers (Mux), optical fiber, and/or demultiplexer (Demux).

Thus FIGS. 14 and 15 illustrate a method of data communication, comprising using an m-plane or semipolar-plane III-Nitride VCSEL or VCSEL array for data communication, wherein the data communication takes advantage of inherent polarization of the electromagnetic radiation emitted from each of the VCSELs or VCSEL array. In one or more examples of the method of data communication, the electromagnetic radiation has a polarization ratio of more than 0.80 along a crystallographic a-direction of the VCSELs and/or the electromagnetic radiation has an emission wavelength in a violet, blue, or green wavelength range.

### 6. Advantages and Improvements

This section of the present disclosure reports on polarization modulation methods using an m-plane or semi-polar III-Nitride VCSEL or VCSEL array. The present invention makes it easier and cheaper to process polarization stable light sources for visible light data communication.

7. References for the Third Embodiment

The following references are incorporated by reference herein.

1. Chen, Z.-Y. et al. Use of polarization freedom beyond polarization-division multiplexing to support high-speed and spectral-efficient data transmission. Light Set. Appl. 6, e16207 (2017).

2. Maldonado, T. Electro-optic Modulators. in

3. Ostennann, Michalzik, R. Polarization Control of VCSELs. in 147-179

4. Haglund, A., Gustaysson, S. J., Vukusic, J., Jedrasik, P. & Larsson, A. High-power fundamental-mode and polarisation stabilised VCSELs using sub-wavelength surface grating. Electron. Lett. 41, 805-807 (2005).

5. Kagami, M. Visible Optical Fiber Communication. Available at: http://www.tytlabs.com/japanese/review/rev402pdf/402_001kagami.pdf. (Accessed: 25 Sep. 2017)

6. Holder, C. O. et al, Nonpolar III-nitride vertical-cavity surface emitting lasers with a polarization ratio of 100% fabricated using photoelectrochemical etching. Appl. Phys. Lett. 105, 031111 (2014).

Nomenclature

As used herein, the terms “III-Nitride”, “III-N”, and “GaN” refer to any alloy of group three (B,Al,Ga,In) nitride semiconductors that are described by B_{w}AlₓGa_{y}In_{z}N, where 0≤w≤1,0≤x≤1, 0≤y≤1, 0≥z≤1, and w+x+y+z=1. Compositions can range from containing a single group three element to all four group III elements. These materials can, and often, include dopants and impurities. “Near-UV” and “violet” light refers to light emitted with a wavelength above 380 nm, but below that of 450 nm. “Blue” light refers to light emitted with a wavelength above 450 nm but below that of 500 nm.

Near-UV” and “violet” light refers to light emitted with a wavelength above 380 nm, but below that of 450 nm, “Horizontal” refers to being parallel to the substrate or submount and perpendicular to the VCSEL output beam. “Phosphor” refers to a material that exhibits luminescence, and does not necessarily limit the substance to a single composition. For example, three different plates could make up the red, green, and blue portions and the total would be considered the “phosphor”. “White light” refers to light that the human eye perceives as white, and is a category containing many different spectral possibilities.

As used herein, the terms “III-Nitride”, “III-N”, and “GaN” refer to any alloy of group three (B,Al,Ga,In) nitride semiconductors that are described by B_{w}AlₓGa_{y}In_{z}N, where 0≤w≤1, 0≤x ≤1, 0≤y≤1, 0≤z≤1, and w+x+y+z =1. Compositions can range from containing a single group three element to all four group III elements. These materials can, and often, include dopants and impurities.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A system, comprising:
a III-Nitride Vertical Cavity Surface Emitting Laser (VCSEL) or III-Nitride VCSEL array emitting electromagnetic radiation having a wavelength in a violet or blue wavelength range; and
an apparatus coupled to the VCSEL or VCSEL array, the apparatus comprising:
a detector positioned to detect fluorescence emitted from at least one fluorescent material in response to the VCSEL or the VCSEL array stimulating the at least one fluorescent material with the electromagnetic radiation, or
a phosphor horizontally on or above the III-Nitride VCSEL or on or above the III-Nitride VCSEL array, or
one or more modulators connected to the VCSEL or VCSEL array.

2. The system of claim 1, wherein the VCSEL or VCSEL array comprises a non-polar or semi-polar III-Nitride material and the system comprises the detector positioned to detect fluorescence.

3. The system of claim 2, wherein:
each of a plurality of the VCSELs are spaced in the array and have an optical aperture with a width emitting a beam of the electromagnetic radiation,
each of the beams stimulate different parts of the fluorescent material or a plurality of the fluorescent materials that are spatially separated, and
the fluorescence emitted from the different parts or from the plurality of the fluorescent materials is used to measure interactions in the fluorescent material or between the fluorescent materials or between materials connected to the fluorescent materials.

4. (canceled)

5. (canceled)

6. The system of claim 1, further comprising a battery powering the VCSEL or the VCSEL array.

7. The system of claim 3, wherein the VCSEL or each of a plurality of the VCSELs in the array irradiate the at least one fluorescent material with a beam having a diameter less than 4 micrometers.

8. The system of claim 2, further comprising a microlens array or lens patterned into III-Nitride material of the VCSEL or patterned into a photoresist on or above the VCSEL, the VCSEL array, or each of a plurality of VCSELs in the VCSEL array.

9. (canceled)

10. (canceled)

11. The apparatus of claim 1, further comprising a an external microlens array bonded to the VCSEL or VCSEL array

12. (canceled)

13. (canceled)

14. (canceled)

15. (canceled)

16. (canceled)

17. The apparatus of claim 1, wherein the system comprises a white light illumination system, comprising:
the phosphor horizontally on or above a III-Nitride Vertical Cavity Surface Emitting Laser (VCSEL) or on or above a III-Nitride VCSEL array.

18. The system of claim 17, further comprising a film or plate attached to VCSEL array, wherein:
the plate or the film includes the phosphor covering a plurality of the VCSELs in the array,
a thickness of the plate or film is less than a length of the film or the plate extending across a surface of the VCSEL array, and
white light is emitted from the phosphor in response to electromagnetic radiation emitted from the VCSELs being absorbed in the phosphor.

19. The system of claim 18, wherein:
the phosphor comprises:
a red phosphor material emitting red light in response to red phosphor material absorbing the electromagnetic radiation,
a green phosphor material emitting green light in response to the green phosphor material absorbing the electromagnetic radiation,
a blue phosphor material emitting blue light in response to the blue phosphor material absorbing the electromagnetic radiation; and
a combination of the blue light, red light, and green light is viewed as the white light.

20. The system of claim 19, wherein the electromagnetic radiation from each of the VCSELs is absorbed by the red phosphor material, the green phosphor material, and the blue phosphor material.

21. The system of claim 19, wherein the red phosphor material, the green phosphor material, and the blue phosphor material are distributed throughout the plate or the film.

22. The system of claim 17, wherein the phosphor comprises a single crystal phosphor or a ceramic phosphor.

23. (canceled)

24. The system of claim 17, further comprising a cooling system below the VCSEL array, wherein the VCSEL array is between the phosphor and the cooling system.

25. The system of claim 17, wherein an emission wavelength of the III-Nitride VCSEL or the III-Nitride VCSEL array is in a violet or blue wavelength range.

26. (canceled)

27. (canceled)

28. (canceled)

29. (canceled)

30. (canceled)

31. (canceled)

32. The system of claim 1 comprising a data communication link, comprising:
the modulators connected to the array of III-Nitride Vertical Cavity Surface Emitting Lasers (VCSELs) each having an m-plane or semipolar plane crystal orientation and emitting polarized electromagnetic radiation.

33. The data communication link of claim 32, wherein:
each of the modulators are connected to and associated with a different one of the VCSELs and modulate a polarization of the electromagnetic radiation emitted from the one of the VCSELs associated with the modulator,
the data link includes a plurality of data channels each transmitting data using the electromagnetic radiation modulated by a different one of the modulators, and
each of the modulators output modulated electromagnetic radiation having a different polarization state.

34. The data communication link of claim 33, wherein each of the modulators shift the polarization comprising a linear polarization by a different number of degrees.

35. (canceled)

36. (canceled)

37. (canceled)

38. The data communication link of claim 32, wherein the electromagnetic radiation has a polarization ratio of more than 0.80 along a crystallographic a-direction of the VCSELs.

39. (canceled)

40. (canceled)

41. (canceled)

42. A method of making an apparatus, comprising:
obtaining a III-Nitride Vertical Cavity Surface Emitting Laser (VCSEL) or III-Nitride VCSEL array emitting electromagnetic radiation having a wavelength in a violet or blue wavelength range; and
connecting a system to the VCSEL or VCSEL array, the system comprising:
a detector positioned to detect fluorescence emitted from at least one fluorescent material in response to the VCSEL or the VCSEL array stimulating the at least one fluorescent material with the electromagnetic radiation, or
a phosphor horizontally on or above the III-Nitride VCSEL or on or above the III-Nitride VCSEL array, or
one or more modulators connected to the VCSEL or VCSEL array.
